(19) United States
(12) Patent Application Publication
(10) Pub. No.: US 2007/0066055 A1
(43) Pub. Date: Mar. 22, 2007

(54) METHOD OF FABRICATING CONDUCTIVE LAYER

(76) Inventors: Chien-Hsin Huang, Taichung City (TW); Wen-Ping Yen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,696

(22) Filed: Sep. 20, 2005

(51) Int. Cl. H01L 21/44

(52) U.S. Cl. 438/658; 438/688; 438/660; 438/669

(57) ABSTRACT

A method of fabricating a patterned conductive layer is provided. First, a conductive layer whose material includes at least aluminum-copper (Al—Cu) alloy is formed on a substrate. Then, a heat treatment process is performed to heat the conductive layer to a temperature higher than the phase change temperature of the Al—Cu alloy. Next, the conductive layer is patterned. The method in the present invention can avoid the formation of metallic educt and facilitate subsequent etching processes.

### BACKGROUND OF THE INVENTION

1. Field of the Invention

The present invention relates to a method of fabricating a semiconductor device. More particularly, the present invention relates to a method of fabricating a conductive layer.

2. Description of the Related Art

The metal aluminum is a major conductive material for fabricating semiconductor devices in most manufacturing plant due to its low electrical resistivity (about 3 Ω·cm) and high cohesiveness with silicon oxide material and the ease of shaping the metallic layer into a specified form through etching. However, because of the intrinsic material properties of aluminum atoms, a suitable amount of copper is frequently added to produce an aluminum-copper alloy that can enhance its resistance against electro-migration.

In general, an aluminum-copper alloy layer serving as a conductive line is formed by depositing aluminum-copper alloy at a temperature between 300° C.˜400° C. After the temperature has dropped to a suitable level, a photoresist layer is coated over the aluminum-copper layer. Thereafter, the photoresist layer is exposed and developed. Finally, the aluminum-copper alloy layer is etched.

FIG. 1 is a phase diagram for the two metallic elements, aluminum and copper. In FIG. 1, the horizontal coordinate represents the copper content in aluminum-copper alloy, the vertical coordinate represent the temperature, α represents a homogeneous mixed solid phase of aluminum and copper; θ represent the compound CuAl₂, and α+θ represents the coexistence of α phase aluminum-copper alloy and θ phase CuAl₂. The line ab represents a solid solution line of the aluminum-copper alloy. The temperature on this line represents the phase change temperature between the α phase and the α+θ phase. In other words, when the temperature of the aluminum-copper alloy is below the phase transition temperature, the θ phase CuAl₂ coexists with the α phase aluminum-copper alloy.

In the processing of the metallic layer, after depositing the aluminum-copper alloy and the temperature dropping to the ambient, the aluminum-copper alloy may be re-heated to a high temperature for performing a machining operation or reworking the photoresist material. Therefore, the original α phase Al—Cu alloy at the low temperature will gradually transform into the α+θ phase Al—Cu alloy and produce CuAl₂ metallic educt. Because the etching rate between the CuAl₂ metallic material on one hand and the α phase Al—Cu alloy on the other hand are different, residual CuAl₂ is often left behind to form hillocks.

The hillocks are defects in the deposited metallic layer because it will cause a drop in the processing yield and a drop in the reliability of the aluminum-copper alloy layer. Furthermore, they may scratch or crack the chip and inconvenience subsequent fabrication processes.

### SUMMARY OF THE INVENTION

Accordingly, the present invention is to provide a method of fabricating a conductive layer capable of preventing the formation of an aluminum-copper alloy with CuAl₂ educt and facilitating subsequent etching processes.

The present invention is to provide a method of fabricating a conductive layer capable of maintaining an aluminum-copper alloy in a homogeneous mixed phase and preventing the formation of defects after a subsequent etching process so that the processing yield can be increased.

To achieve these and other advantages and in accordance with the purpose of the invention, as embodied and broadly described herein, the invention provides a method of fabricating a patterned conductive layer. First, a conductive layer whose material includes at least aluminum-copper (Al—Cu) alloy is formed. Then, a heat treatment process is performed to heat the conductive layer to a temperature higher than the phase change temperature of the Al—Cu alloy. Thereafter, the conductive layer is patterned.

According to the aforementioned method of fabricating a patterned conductive layer in the embodiment of the present invention, the percentage by weight of the copper in the aluminum-copper alloy is smaller than 5.7%, for example, 0.5%.

According to the aforementioned method of fabricating a patterned conductive layer in the embodiment of the present invention, before performing the heat treatment, further includes performing a treatment to transform the aluminum-copper alloy having a homogeneous mixed aluminum-copper phase gradually into aluminum-copper alloy comprising CuAl₂. Such a treatment is a photoresist reworking process, for example.

According to the aforementioned method of fabricating a patterned conductive layer in the embodiment of the present invention, the temperature for forming the conductive layer is between 250° C. to 650° C.

According to the aforementioned method of fabricating a patterned conductive layer in the embodiment of the present invention, the heat treatment is a plasma-enhanced chemical vapor deposition process carried out for a period of 3 seconds or more, for example. The heat treatment can be carried out using a heater.

According to the aforementioned method of fabricating a patterned conductive layer in the embodiment of the present invention, the aluminum-copper alloy may further include silicon.

The present invention also provides an alternative method of fabricating a conductive layer. First, a conductive material layer is formed on a substrate. The conductive material layer comprises at least aluminum-copper alloy. Then, a first photoresist layer is formed on the conductive material layer. Thereafter, a photoresist reworking process is carried out to remove the first photoresist layer. After that, a heat treatment of the conductive material layer is carried out by heating the conductive material layer to a temperature higher than the phase transition temperature of the aluminum-copper alloy. Next, a second photoresist layer is formed on the conductive material layer. Using the second photoresist layer as a mask, the conductive material layer is etched. Finally, the second photoresist layer is removed.

According to the aforementioned method of fabricating a conductive layer in the embodiment of the present invention, the percentage by weight of copper in the aluminum-copper alloy is lower than 5.7%, for example, 0.5%.

According to the aforementioned method of fabricating a conductive layer in the embodiment of the present invention, the temperature for forming the conductive material layer is between 250° C. to 650° C.

According to the aforementioned method of fabricating a conductive layer in the embodiment of the present invention, the method of removing the first photoresist layer includes performing a plasma ashing process, for example.

According to the aforementioned method of fabricating a conductive layer in the embodiment of the present invention, CuAl₂ has existed in the conductive material layer before performing the heat treatment but after performing the photoresist reworking process.

According to the aforementioned method of fabricating a conductive layer in the embodiment of the present invention, the heat treatment is a plasma-enhanced chemical vapor deposition process carried out for a period of 3 seconds or more, for example. The heat treatment can be carried out using a heater.

According to the aforementioned method of fabricating a conductive layer in the embodiment of the present invention, the aluminum-copper alloy may further include silicon.

In the present invention, an additional heat treatment is performed after forming a conductive layer but before etching the conductive layer. Therefore, the components of the aluminum-copper alloy can be maintained and the formation of the 0 phase CuAl₂ can be avoided. The heat treatment not only facilitates subsequent etching processes and prevents the formation of defects, but also increases the production yield.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a phase diagram for the two metallic elements, aluminum and copper.

FIG. 2 is a flow diagram showing the steps for forming a conductive layer according to one embodiment of the present invention.

FIG. 3 is a flow diagram showing the steps for forming a conductive layer according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

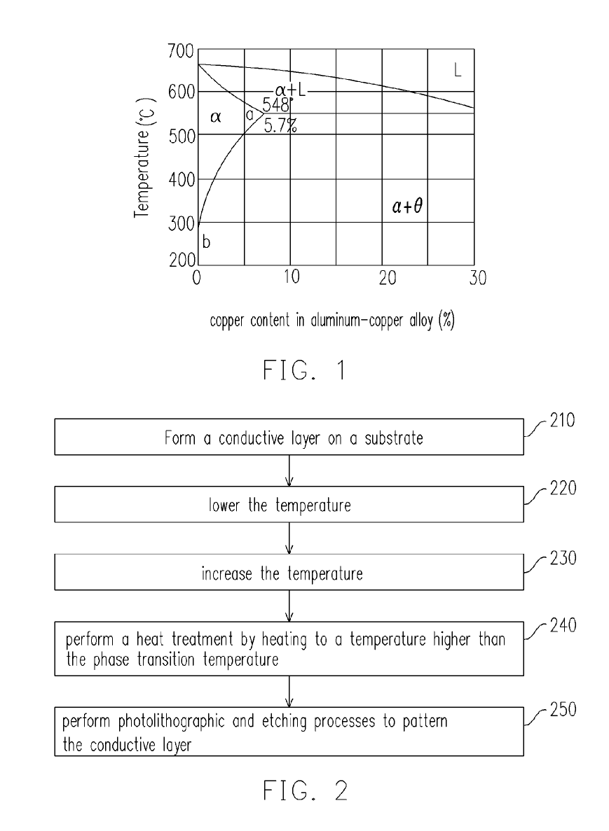

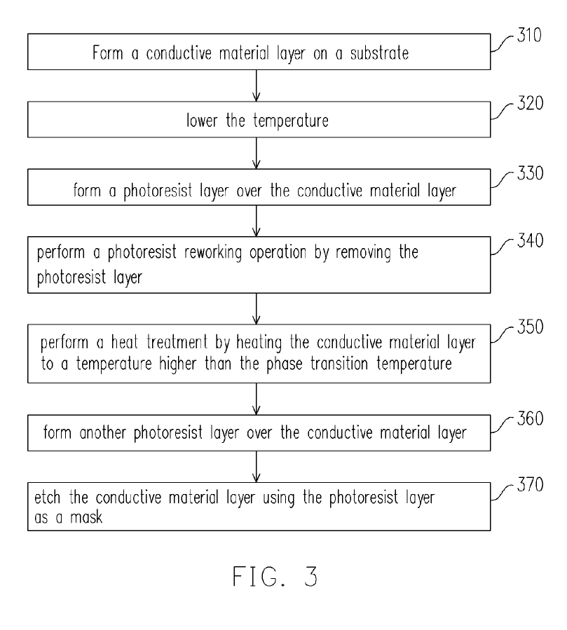

FIG. 2 is a flow diagram showing the steps for forming a conductive layer according to one embodiment of the present invention. As shown in FIG. 2, the present invention provides a method for fabricating a patterned conductive layer. The patterned conductive layer is a plug or a conductive line in metallic interconnects, for example. First, a conductive layer (in step 210) is formed on a substrate. Devices, such as NMOS, PMOS, CMOS or other memory is formed on the substrate. In addition, a barrier layer may also form over the substrate before forming the conductive layer. The barrier layer is a titanium/titanium nitride composite layer, for example. The conductive layer is an aluminum-copper alloy composing of a homogeneous mixture of aluminum and copper. The aluminum-copper alloy may also be doped with few silicon. The method of forming the conductive layer includes performing a physical vapor deposition process, such as a direct current plasma sputtering process, a high-temperature sputtering process or a high-pressure sputtering process at a temperature between 250° C.˜650° C., and preferably between 300° C.˜400° C.

After depositing the conductive layer but before performing the photolithographic process, the conductive layer is cooled down (step 220) to facilitate the subsequent photoresist coating, exposure and development process. After that, the conductive layer is heated to a higher temperature (step 230) because of machine operation or photoresist reworking process. The heating up process transfers energy to the conductive layer so that the homogeneously mixed α phase aluminum-copper alloy after the cooling process starts to have a phase change and transform gradually into α+θ phase aluminum-copper alloy. In other words, the component of the aluminum-copper alloy is no longer a homogeneous mixture of AlCu but includes some θ phase CuAl₂. The heating process includes heating the conductive layer to a temperature between 150° C.˜250° C., for example.

To resolve the problem of having CuAl₂ educt, a heat treatment is carried out by heating the conductive layer to a temperature higher than the phase transition temperature (step 240). Thus, the transformed α+θ phase aluminum-copper alloy is returned to the original α phase aluminum-copper alloy. To perform the heat treatment, the conductive layer is placed inside a plasma-enhanced chemical vapor deposition chamber and processed for 3 seconds or more, for example, 5 to 20 seconds. Obviously, the heat treatment can be achieved through heating the substrate on a hot plate or performing a rapid thermal processing (RTP) and not just limited to a plasma-enhanced chemical vapor deposition method. Alternatively, the conductive layer is heated using a heating element. The temperature for carrying out the heat treatment must be greater than the phase transition temperature, for example, above 300° C., such as 300° C.˜500° C. Obviously, depending on the aluminum content and the copper content in the aluminum-copper alloy, the temperature for treating the aluminum-copper alloy should be adjusted. In other words, there is no fixed temperature range for carrying out the heat treatment.

Thereafter, photolithographic and etching processes are carried out to transform the conductive layer into a patterned conductive layer (step 250). Obviously, the photolithographic process includes coating a photoresist layer, performing an exposure process, a development process and an etching process. The etching process includes performing a dry etching or a wet etching operation. A detailed description is omitted for that these methods should be familiar to those skilled in this field.

The aforesaid heat treatment can prevent the formation of CuAl₂ educt and the production of residues after etching the aluminum-copper alloy. Consequently, not only is the yield increased, but the reliability of the device is also improved.

To explain the application of the present invention further, the following description includes a photoresist reworking process as an example to show the method of the present invention. FIG. 3 is a flow diagram showing the steps for forming a conductive layer according to another embodiment of the present invention. First, as shown in FIG. 3, a conductive material layer (in step 310) is formed on a substrate. Devices, such as NMOS, PMOS, CMOS or other memory, is formed on the substrate. In addition, a barrier layer may also be formed over the substrate before forming the conductive layer. The barrier layer can be a titanium/titanium nitride composite layer, for example. The conductive layer is an aluminum-copper alloy composing of a homogeneous mixture of aluminum and copper (the α phase aluminum-copper alloy in FIG. 1). The percentage by weight of copper in the aluminum-copper alloy is smaller than 5.7%, preferably about 0.5%, for example. The aluminum-copper alloy may also be doped with few silicon. The method of forming the conductive material layer includes performing a physical vapor deposition process, such as a direct current plasma sputtering process, a high-temperature sputtering process or a high-pressure sputtering process at a temperature between 250° C.˜650° C., and preferably between 300° C.˜400° C.

After depositing the conductive layer but before performing the photolithographic process, the conductive material layer is cooled down (step 320) to facilitate the subsequent photolithographic process. Then, a photoresist layer is formed on the conductive material layer (step 330). The method of forming the photoresist layer includes, for example, performing a spin coating to form a photoresist layer over the conductive material layer and performing a exposure to transfer the pattern to the photoresist layer.

After developing the photoresist layer but before carrying out the next step, a quality control action known as an after develop inspection (ADI) is prosecuted. If the photoresist pattern after the exposure has some twisting deformation in the pattern or some overlay error, the photoresist layer must be removed and a photoresist reworking operation must be carried out (step 340). The method of removing the photoresist layer includes performing a dry plasma ashing process. When a plasma ashing process is performed to remove the photoresist, the conductive material layer will be heated to a high temperature, for example, between 150° C.˜250° C. This will cause the originally stable α phase aluminum-copper alloy to transform slowly into α+θ phase aluminum-copper alloy and produce θ phase educt (CuAl₂).

Thereafter, a heat treatment is performed by heating the conductive material layer to a temperature higher than the phase transition temperature (step 350) so that the α+θ phase aluminum-copper alloy can return to the original α phase aluminum-copper alloy. The conductive material layer is positioned inside a plasma-enhanced chemical vapor deposition chamber and the heat treatment is performed for a period of 3 seconds or more, preferably between 5 seconds to 20 seconds. Obviously, the heat treatment can be achieved through heating the substrate on a hot plate or performing a rapid thermal processing (RTP) and not just limited to a plasma-enhanced chemical vapor deposition method. The temperature used in the heat treatment is higher than the phase transition temperature of the aluminum-copper alloy, for example, above 300° C., such as between 300° C.˜500° C. Obviously, depending upon the aluminum content and copper content in the aluminum-copper alloy, the phase transition temperature of the aluminum-copper alloy may change. Therefore, the driving temperature in the heat treatment should be adjusted according to the component contents of the aluminum-copper alloy rather than fixed within a definite temperature range.

Then, another photoresist layer is formed on the conductive material layer (step 360). The method of forming the photoresist layer is identical to the method of forming the previous photoresist layer. Similarly, a spin coating process is performed to form a photoresist layer over the conductive material layer and then performing exposure and development to transfer a pattern to the photoresist layer. Thereafter, using the photoresist layer as an etching mask, the conductive material layer underneath is etched to form a patterned conductive layer (step 370). Finally, the photoresist layer is removed. After completing the etching operation, the remaining conductive layer serves as the plugs or wire lines of the metallic interconnects.

The aforesaid heat treatment can prevent the formation of CuAl₂ educt after re-heating the cooled down aluminum-copper alloy and hence avoid the accumulation of residues after etching the aluminum-copper alloy. Consequently, not only is the yield increased, but the reliability of the device is also improved.

In summary, the present invention provides an additional heat treatment after forming a conductive material layer but before etching the conductive material layer so that the temperature of the alloy is raised to a level higher than its phase transition temperature. Therefore, the constituent composition of the aluminum-copper alloy can be maintained and the formation of the θ phase CuAl₂ can be avoided. The heat treatment not only facilitates subsequent etching processes and prevents the formation of defects, but also increases the production yield. Moreover, possible damages to the chip resulting from scratching by the CuAl₂ residues can also be prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a patterned conductive layer, comprising the steps of:
forming a conductive layer, wherein the conductive layer comprises at least aluminum-copper alloy;
performing a heat treatment of the conductive layer by heating the conductive layer to a temperature higher than the phase transition temperature of the aluminum-copper alloy; and
patterning the conductive layer.

2. The method of claim 1, wherein the percentage by weight of the copper in the aluminum-copper alloy is smaller than 5.7%.

3. The method of claim 2, wherein the percentage by weight of the copper in the aluminum-copper alloy is about 0.5%.

4. The method of claim 1, wherein before performing the heat treatment, further includes performing another treatment that gradually transforms the aluminum-copper alloy having a homogeneous mixed aluminum-copper phase into one comprising CuAl₂ compound.

5. The method of claim 4, wherein the treatment includes a photoresist reworking process.

6. The method of claim 1, wherein the conductive layer is formed within the temperature range 250° C. to 650° C.

7. The method of claim 1, wherein the heat treatment includes performing a plasma-enhanced chemical vapor deposition process.

8. The method of claim 1, wherein the heat used in the heat treatment is provided through a heater.

9. The method of claim 1, wherein the aluminum-copper alloy further includes few silicon.

10. A method of fabricating a conductive layer, comprising the steps of:
forming a conductive material layer on a substrate, wherein the conductive material layer comprises at least aluminum-copper alloy;
forming a first photoresist layer over the conductive material layer;
performing a photoresist reworking operation to remove the first photoresist layer;
performing a heat treatment on the conductive material layer by heating the conductive material layer to a temperature higher than the phase transition temperature of the aluminum-copper alloy;
forming a second photoresist layer over the conductive material layer;
etching the conductive material layer using the second photoresist layer as a mask; and
removing the second photoresist layer.

11. The method of claim 10, wherein the percentage by weight of the copper in the aluminum-copper alloy is smaller than 5.7%.

12. The method of claim 10, wherein the percentage by weight of the copper in the aluminum-copper alloy is about 0.5%.

13. The method of claim 10, wherein the conductive material layer is formed within the temperature range 250° C. to 650° C.

14. The method of claim 10, wherein the step of removing the first photoresist layer includes performing a plasma ashing process.

15. The method of claim 10, wherein after performing the photoresist reworking operation but before performing the heat treatment, the conductive material layer contains some CuAl₂ compound.

16. The method of claim 10, wherein the heat treatment includes performing a plasma-enhanced chemical vapor deposition process.

17. The method of claim 10, wherein the heat used in the heat treatment is provided by a heater.

18. The method of claim 10, wherein the aluminum-copper alloy comprises few silicon.
